(19) United States
(12) Patent Application Publication
(10) Pub. No.: US 2026/0361284 A1
(43) Pub. Date: Nov. 12, 2026

(54) ACOUSTIC WAVE RESONATOR, ACOUSTIC WAVE FILTER, FRONT END MODULE, AND COMMUNICATION DEVICE

(71) Applicant: Murata Manufacturing Co., Ltd., Nagaokakyo-shi (JP)

(72) Inventor: Takashi IWAMOTO, Nagaokakyo-shi (JP)

(21) Appl. No.: 19/734,464

(22) Filed: Jul. 8, 2026

Related U.S. Application Data
(63) Continuation of application No. PCT/JP2025/005014, filed on Feb. 14, 2025.

(30) Foreign Application Priority Data
Feb. 27, 2024 (JP) 2024-027860

(51) Int. Cl. H03H 9/02; H03H 9/17; H03H 9/54; H04B 1/00

(52) U.S. Cl. CPC H03H 9/02015; H03H 9/02133; H03H 9/174; H03H 9/54; H04B 1/0057

(57) ABSTRACT

An acoustic wave resonator includes a support including a support board, a piezoelectric layer at a main surface of the support, and functional electrodes on opposite main surfaces of the piezoelectric layer. The piezoelectric layer includes a first piezoelectric layer with a polarization direction oriented in a first direction, a second piezoelectric layer between the first piezoelectric layer and the main surface of the support, and with a polarization direction oriented in a second direction different from the first direction, and a low-density layer between the first and second piezoelectric layers, and having a density lower than a density of the first piezoelectric layer and a density of the second piezoelectric layer. The first piezoelectric layer, the second piezoelectric layer, and the low-density layer include monocrystals. The low-density layer includes a first portion and a second portion with different densities in a plan view.

### CROSS REFERENCE TO RELATED APPLICATIONS

This application claims the benefit of priority to Japanese Patent Application No. 2024-027860 filed on Feb. 27, 2024 and is a Continuation Application of PCT Application No. PCT/JP2025/005014 filed on Feb. 14, 2025. The entire contents of each application are hereby incorporated herein by reference.

### BACKGROUND OF THE INVENTION

### 1. Field of the Invention

The present invention relates to acoustic wave resonators, acoustic wave filters, front end modules, and communication devices.

### 2. Description of the Related Art

U.S. Patent Application Publication No. 2022/0321100 describes an acoustic wave resonator including upper and lower electrodes and two piezoelectric layers laminated between the upper and lower electrodes. The polarization directions of the two piezoelectric layers are reversed relative to each other.

### SUMMARY OF THE INVENTION

The acoustic wave resonator described in U.S. Patent Application Publication No. 2022/0321100 may cause unwanted waves of various modes, and lower the resonator characteristics.

Example embodiments of the present invention provide acoustic wave resonators, acoustic wave filters, front end modules, and communication devices each capable of improving resonator characteristics.

An acoustic wave resonator according to an example embodiment includes a support that includes a support board, a piezoelectric layer at a main surface of the support, and a plurality of functional electrodes on opposite main surfaces of the piezoelectric layer, wherein the piezoelectric layer includes a first piezoelectric layer having a polarization direction oriented in a first direction, a second piezoelectric layer between the first piezoelectric layer and the main surface of the support, and having a polarization direction oriented in a second direction different from the first direction, and a low-density layer between the first piezoelectric layer and the second piezoelectric layer, and having a density lower than a density of the first piezoelectric layer and a density of the second piezoelectric layer, the first piezoelectric layer, the second piezoelectric layer, and the low-density layer include monocrystals, and the low-density layer includes a first portion and a second portion having different densities in a plan view.

An acoustic wave filter according to an example embodiment includes an acoustic wave resonator according to another example embodiment.

A front end module according to an example embodiment includes an acoustic wave filter according to another example embodiment.

A communication device according to an example embodiment includes a front end module according to another example embodiment.

The acoustic wave resonators, the acoustic wave filters, the front end modules, and the communication devices according to example embodiments of the present invention each improve resonator characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of an acoustic wave resonator according to a first example embodiment of the present invention.

FIG. 2 is a cross-sectional view taken along line II-II′ in FIG. 1.

FIG. 3 is a diagram describing a relationship between a piezoelectric layer and stress distribution of bulk waves.

FIG. 4 is a cross-sectional transmission electron microscope (TEM) image of a piezoelectric layer according to a first example.

FIG. 5 is a graph describing a relationship between the density ratio of a low-density layer in a first example, and the bonding strength.

FIG. 6 is a table describing a relationship, in an acoustic wave resonator according to the first example, between a mean density ratio of the low-density layer, the thickness of the low-density layer, and the presence/absence of an unwanted wave attenuation effect.

FIG. 7 is a table describing a relationship, in the acoustic wave resonator according to the first example, between an in-plane density variation ratio of the low-density layer and the presence/absence of an unwanted wave attenuation effect.

FIG. 8 is a table describing in-plane density distribution of low-density layers according to the first example and a first comparative example.

FIG. 9 is a graph describing a relationship between the density ratio of a low-density layer according to a second example and the bonding strength.

FIG. 10 is a table describing the relationship, in an acoustic wave resonator according to a second example, between the mean density ratio of the low-density layer, the thickness of the low-density layer, and the presence/absence of an unwanted wave attenuation effect.

FIG. 11 is a table describing the relationship, in the acoustic wave resonator according to the second example, between the in-plane density variation ratio of the low-density layer and the presence/absence of an unwanted wave attenuation effect.

FIG. 12 is a table describing in-plane density distribution of low-density layers according to the second example and a second comparative example.

FIG. 13 is a diagram describing a method for manufacturing the acoustic wave resonator according to the first example embodiment of the present invention.

FIG. 14 is a table describing the relationship, in the piezoelectric layer in the first example, between the surface roughness before bonding, the heating temperature after bonding, and the mean density of the low-density layer.

FIG. 15 is a table describing the relationship, in the piezoelectric layer in the second example, between the surface roughness before bonding, the heating temperature after bonding, and the mean density of the low-density layer.

FIG. 16 is a diagram of a communication device according to a second example embodiment of the present invention.

FIG. 17 is a cross-sectional view of an acoustic wave resonator according to a modification example of an example embodiment of the present invention.

### DETAILED DESCRIPTION OF THE EXAMPLE EMBODIMENTS

Hereafter, example embodiments of the present disclosure are described in detail with reference to the drawings. The present disclosure is not limited to these example embodiments. The example embodiments described in the present disclosure are mere examples, and components in different example embodiments may be replaced with each other or combined with each other. In modification examples and second and following example embodiments, matters common to those in the first example embodiment are omitted, and only different points are described. Particularly, the same effects produced by the same configuration are not described for each of the example embodiments.

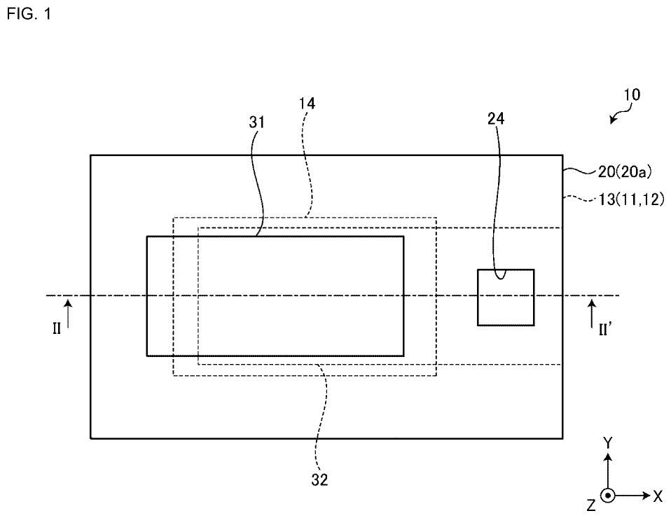

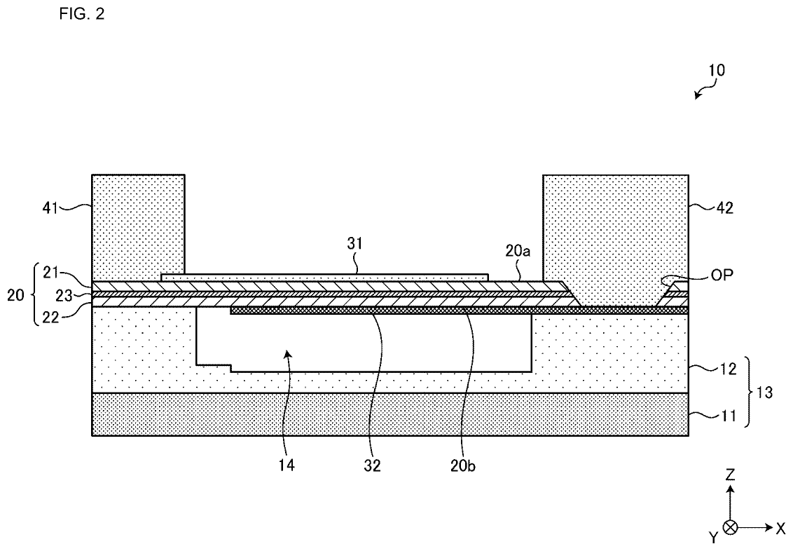

FIG. 1 is a plan view of an acoustic wave resonator according to a first example embodiment. FIG. 2 is a cross-sectional view taken along line II-II′ in FIG. 1. An acoustic wave resonator 10 according to a first example embodiment is a resonator using bulk waves, or more specifically, a bulk acoustic wave (BAW) device.

As illustrated in FIG. 1 and FIG. 2, the acoustic wave resonator 10 includes a support 13, a piezoelectric layer 20, an upper electrode 31, a lower electrode 32, and connection electrodes 41 and 42. As illustrated in FIG. 2, the lower electrode 32, the piezoelectric layer 20, the upper electrode 31, and the connection electrodes 41 and 42 are laminated in this order on the support 13.

In the description below, the thickness direction of the piezoelectric layer 20 is described as a Z-direction, a direction orthogonal to the Z-direction is described as an X-direction, and a direction orthogonal to the Z-direction and the X-direction is described as a Y-direction. The X-direction and the Y-direction are parallel to the surface (a first main surface 20a) of the piezoelectric layer 20. In the description below, a plan view represents a positional relationship when viewed in a direction (Z-direction) orthogonal to the first main surface 20a of the piezoelectric layer 20.

The support 13 faces a second main surface 20b of the piezoelectric layer 20. The support 13 includes a support board 11 and an intermediate layer 12. The support board 11 includes, for example, silicon (Si) or crystals. The intermediate layer 12 is between the support board 11 and the piezoelectric layer 20. The intermediate layer 12 includes an insulating material such as silicon oxide. The support 13 may include no intermediate layer 12, and may receive the piezoelectric layer 20 on the support board 11. More specifically, the piezoelectric layer 20 is bonded to the support board 11 directly or with the intermediate layer 12 (an insulating layer) interposed therebetween.

The support 13 (the intermediate layer 12) includes a recess 1 (a cavity) on a surface facing the second main surface 20b of the piezoelectric layer 20. In a plan view, the recess 14 is positioned to overlap an excitation area of a resonator formed by overlapping the piezoelectric layer 20, the upper electrode 31, and the lower electrode 32. Thus, the energy loss of bulk waves is reduced during excitation, and preferable resonance characteristics can be obtained.

The piezoelectric layer 20 is a flat board having the first main surface 20a and the second main surface 20b opposite the first main surface 20a. The piezoelectric layer 20 is a board including monocrystals of lithium niobate (LiNbO₃) or lithium tantalate (LiTaO₃). Although the thickness of the piezoelectric layer 20 is not particularly limited, the thickness is preferably less than or equal to 1 μm, for example.

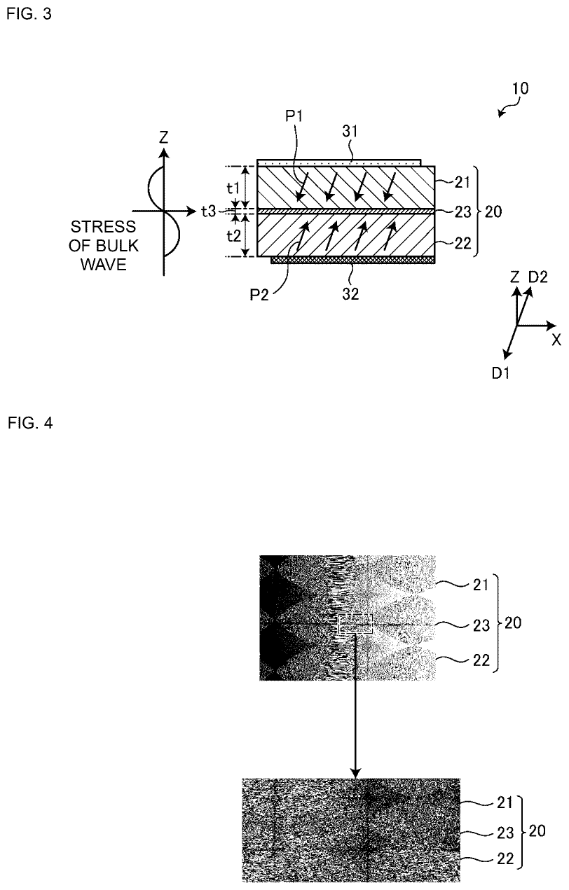

The piezoelectric layer 20 includes a first piezoelectric layer 21, a second piezoelectric layer 22 between the first piezoelectric layer 21 and the main surface of the support 13, and a low-density layer 23 between the first piezoelectric layer 21 and the second piezoelectric layer 22. More specifically, the piezoelectric layer 20 is formed by laminating the second piezoelectric layer 22, the low-density layer 23, and the first piezoelectric layer 21 in this order on the support 13. The first piezoelectric layer 21, the low-density layer 23, and the second piezoelectric layer 22 are monocrystals of the same material. In the present disclosure, to include the same material indicates to include substances with the same empirical formula. The detailed structures of the first piezoelectric layer 21, the low-density layer 23, and the second piezoelectric layer 22 are described with reference to FIG. 3 and subsequent drawings.

That the first piezoelectric layer 21, the low-density layer 23, and the second piezoelectric layer 22 included in the piezoelectric layer 20 in example embodiments of the present disclosure include “monocrystals” indicates that all the crystal orientations of the layers can be identified. More specifically, when the first piezoelectric layer 21, the low-density layer 23, and the second piezoelectric layer 22 included in the piezoelectric layer 20 include lithium niobate or lithium tantalate, and the a-axis and the c-axis of the crystals can be identified, these layers can be considered monocrystals of lithium niobate or lithium tantalate. Whether the crystal orientation of the piezoelectric layer 20 can be identified is determined by measuring the cross section of the piezoelectric layer 20 laminated in the Z-direction for each of the layers, with X-ray diffraction (XRD). Instead of being including monocrystals, the piezoelectric layer 20 may partially include an amorphous area or an area containing defects or a grain boundary due to, for example, manufacturing variations.

The upper electrode 31 and the lower electrode 32 (multiple functional electrodes) are respectively disposed on the first main surface 20a and the second main surface 20b of the piezoelectric layer 20, opposite each other. More specifically, the upper electrode 31 is disposed on the first main surface 20a of the piezoelectric layer 20. The lower electrode 32 is disposed on the second main surface 20b of the piezoelectric layer 20.

As illustrated in FIG. 1 and FIG. 2, a portion of the upper electrode 31 and a portion of the lower electrode 32 overlap in an area overlapping the recess 14. In other words, in an area overlapping the recess 14, the piezoelectric layer 20 is between the upper electrode 31 and the lower electrode 32 in the Z-direction. Thus, bulk waves are propagated between the upper electrode 31 and the lower electrode 32. In the description below, in a plan view, an area in which the upper electrode 31 and the lower electrode 32 overlap may be described as a resonator excitation area.

The upper electrode 31 extends in the X-direction from the area overlapping the recess 14, and is connected to a connection electrode 41, different from the upper electrode 31. The lower electrode 32 extends from the area overlapping the recess 14, on the side opposite the upper electrode 31, and is connected to the connection electrode 42 through an opening OP in the piezoelectric layer 20.

The upper electrode 31 and the lower electrode 32 include a metal such as aluminum (Al), platinum (Pt), copper (Cu), tungsten (W), molybdenum (Mo), or ruthenium (Ru), or an alloy containing at least one of these materials. The upper electrode 31 and the lower electrode 32 may be multilayer films. Between the upper electrode 31 and the lower electrode 32 and the support 13 (the intermediate layer 12), a contact layer including, for example, Ti or NiCr may be provided.

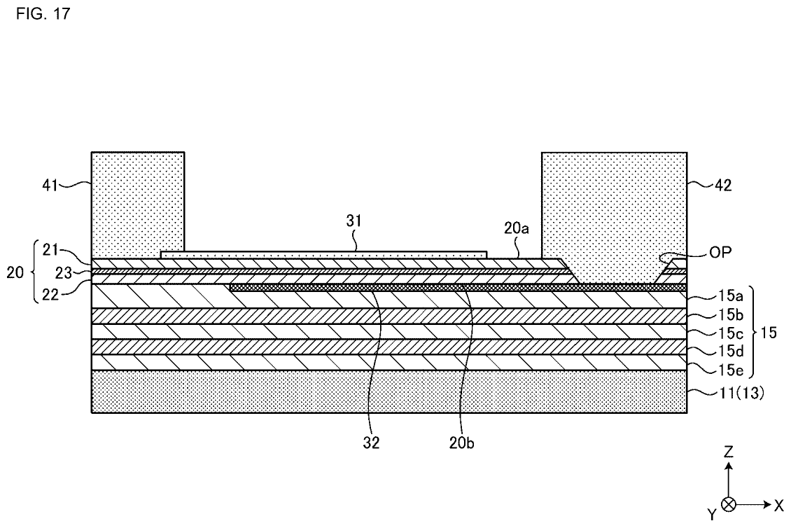

FIG. 17 is a cross-sectional view of an acoustic wave resonator according to a modification example. As illustrated in FIG. 17, instead of the recess 14, the support 13 may include an acoustic multilayer film 15. The acoustic multilayer film 15 has a multilayer structure including low-acoustic-impedance layers 15a, 15c, and 15e having relatively low acoustic impedance, and high-acoustic-impedance layers 15b and 15d having relatively high acoustic impedance. The low-acoustic-impedance layers 15a, 15c, and 15e are, for example, dielectric films including SiO₂, SiOC, or polymers or metal layers including Al. The high-acoustic-impedance layers 15b and 15d are, for example, metal layers including W, Pt, or Mo, or dielectric layers including hafnium oxide, tantalum oxide, tungsten oxide, or aluminum nitride. When the support 13 includes the acoustic multilayer film 15, the support 13 can confine bulk waves within the piezoelectric layer 20 without using the recess 14.

In a plan view, the upper electrode 31, the lower electrode 32, and the recess 14 are rectangular, but may have any shape such as a circle.

With reference to FIG. 3, the detailed structures of the first piezoelectric layer 21, the low-density layer 23, and the second piezoelectric layer 22 in the piezoelectric layer 20 are described. FIG. 3 illustrates the relationship between the piezoelectric layers and stress distribution of bulk waves.

In FIG. 3, arrows P1 indicate the polarization direction of the first piezoelectric layer 21. Arrows P2 indicate the polarization direction of the second piezoelectric layer 22. As illustrated in FIG. 3, the first piezoelectric layer 21 is in contact with the upper electrode 31, and is positioned at the top of the piezoelectric layer 20. The polarization direction (arrows P1) of the first piezoelectric layer 21 is a first direction D1. The second piezoelectric layer 22 is in contact with the lower electrode 32, and is positioned at the bottom of the piezoelectric layer 20. The polarization direction (arrows P2) of the second piezoelectric layer 22 is a second direction D2, different from the first direction D1.

The first direction D1 and the second direction D2 are directions intersecting the X-direction, the Y-direction, and the Z-direction. More specifically, the polarization directions of the first piezoelectric layer 21, the low-density layer 23, and the second piezoelectric layer 22 intersect the thickness direction (Z-direction) of the piezoelectric layer 20.

The polarization directions of the first piezoelectric layer 21 and the second piezoelectric layer 22 are described in relation to the Z-direction component and the horizontal direction component (a direction parallel to the surface defined by the X-direction and the Y-direction) separately. The Z-direction component in the polarization direction (first direction D1) of the first piezoelectric layer 21 is in the opposite direction to the Z-direction component in the polarization direction (second direction D2) of the second piezoelectric layer 22. The horizontal direction component in the polarization direction (first direction D1) of the first piezoelectric layer 21 is in the opposite direction to the horizontal direction component in the polarization direction (second direction D2) of the second piezoelectric layer 22.

The low-density layer 23 is between the first piezoelectric layer 21 and the second piezoelectric layer 22. The low-density layer 23 includes a same material as the material of at least one of the first piezoelectric layer 21 or the second piezoelectric layer 22, and monocrystals having the same crystal structure and the same crystal orientation as the material of at least one of the first piezoelectric layer 21 or the second piezoelectric layer 22. The low-density layer 23 has a lower density than the first piezoelectric layer 21 and the second piezoelectric layer 22. The low-density layer 23 has a density variation in a plan view. In other words, the low-density layer 23 includes a first portion and a second portion that have different densities in a plan view. For example, the first portion is an area having a relatively high density, and the second portion is an area having a relatively low density. However, both the first portion and the second portion have a lower density than the first piezoelectric layer 21 and the second piezoelectric layer 22.

Although the polarization direction of the low-density layer 23 is not illustrated in FIG. 3, the polarization direction of the low-density layer 23 is the same as at least one of the polarization direction of the first piezoelectric layer 21 or the polarization direction of the second piezoelectric layer 22. Alternatively, the low-density layer 23 may include a portion in which the polarization direction is oriented in the first direction D1 and a portion in which the polarization direction is oriented in the second direction D2.

As illustrated in FIG. 3, a thickness t1 of the first piezoelectric layer 21 is equivalent to a thickness t2 of the second piezoelectric layer 22. A thickness t3 of the low-density layer 23 is less than the thickness t1 of the first piezoelectric layer 21 and the thickness t2 of the second piezoelectric layer 22. For example, the thickness t1 of the first piezoelectric layer 21 and the thickness t2 of the second piezoelectric layer 22 are approximately greater than or equal to 50 nm and less than or equal to 600 nm. The thickness t3 of the low-density layer 23 is approximately greater than or equal to 0.2 nm and less than or equal to 30 nm, for example. More specifically, the thickness t3 of the low-density layer 23 is approximately greater than or equal to 0.2 nm and less than or equal to 20 nm, for example.

The case in which “the thickness is equivalent” is not limited to the case in which the thickness is completely the same, and includes a case in which the difference in thickness is within the range greater than or equal to ±5% and less than or equal to ±5%, for example.

When a wavelength of a high-frequency signal, in the piezoelectric layer 20, transmitted between the upper electrode 31 and the lower electrode 32 is defined as λ, the thickness t1 of the first piezoelectric layer 21 is λ/2, and the thickness t2 of the second piezoelectric layer 22 is λ/2. The thickness t3 of the low-density layer 23 is much less than λ/2.

With the above structure, a main bulk wave resonance is established with establishment of a half-wavelength resonance in each of the first piezoelectric layer 21 and the second piezoelectric layer 22. The stress in the piezoelectric layer 20 produced by the main bulk wave is maximum at the center portion of the first piezoelectric layer 21 in the Z-direction and at the center portion of the second piezoelectric layer 22 in the Z-direction. The stress in the piezoelectric layer 20 produced by the main bulk wave is minimum at the position overlapping the low-density layer 23. Thus, regardless of whether the piezoelectric layer 20 includes the low-density layer 23, energy loss of a main bulk wave is reduced.

An acoustic wave in a mode with a higher electromechanical coupling coefficient is less susceptible to energy loss in the low-density layer 23, and an acoustic wave in a mode with a lower electromechanical coupling coefficient is more susceptible to energy loss in the low-density layer 23. Thus, a harmonic wave in unwanted waves different from a main bulk wave has greater energy loss in the low-density layer 23 as compared to the main bulk wave, and is thus reduced.

In contrast, in unwanted waves different from a main bulk wave, the position in the Z-direction indicating the minimum value of stress is displaced from the low-density layer 23. In other words, in the low-density layer 23, stress caused by unwanted waves is greater than stress caused by the main bulk wave. The low-density layer 23 has a density variation in a plan view. Thus, a large number of unwanted waves that pass through different areas of the low-density layer 23 interfere with each other, and are thus reduced. The acoustic wave resonator 10 according to the present example embodiment can thus reduce unwanted waves while reducing attenuation of a main bulk wave, as compared to a structure not including the low-density layer 23. The acoustic wave resonator 10 can thus improve the resonator characteristics.

Examples of unwanted waves different from a main bulk wave include a wave in a mode starting from the upper surface of the upper electrode 31 or the lower surface of the lower electrode 32, and a wave in a mode starting from the edge of a membrane portion of the piezoelectric layer 20.

With reference to FIG. 4 to FIG. 7, the low-density layer 23 in an acoustic wave resonator 10 according to a first example is described in detail now. In the acoustic wave resonator 10 according to the first example, the first piezoelectric layer 21, the second piezoelectric layer 22, and the low-density layer 23 include the same monocrystals of lithium niobate (LiNbO₃).

FIG. 4 is a cross-sectional transmission electron microscope (TEM) image of a piezoelectric layer according to the first example. The upper diagram in FIG. 4 is a transmission electron microscope dark-field (TEM-DF) image of the piezoelectric layer 20, and the lower diagram in FIG. 4 is an enlarged transmission electron microscope bright-field (TEM-BF) image of an interfacial portion of the first piezoelectric layer 21, the second piezoelectric layer 22, and the low-density layer 23 in the upper diagram in FIG. 4.

As illustrated in FIG. 4, in each of the TEM-DF image and the TEM-BF image, the low-density layer 23 is expressed in a shade closer to black, as compared to the first piezoelectric layer 21 and the second piezoelectric layer 22. In the cross-sectional TEM image, portions with higher densities appear whiter, and portions with lower densities appear blacker. The drawing thus illustrates that the low-density layer 23 has a lower density than the first piezoelectric layer 21 and the second piezoelectric layer 22.

Although not illustrated, the density variation (the first portion and the second portion with different densities (refer to FIG. 8)) of the low-density layer 23 in a plan view can be identified by capturing multiple cross-sectional TEM images illustrated in FIG. 4 in different areas.

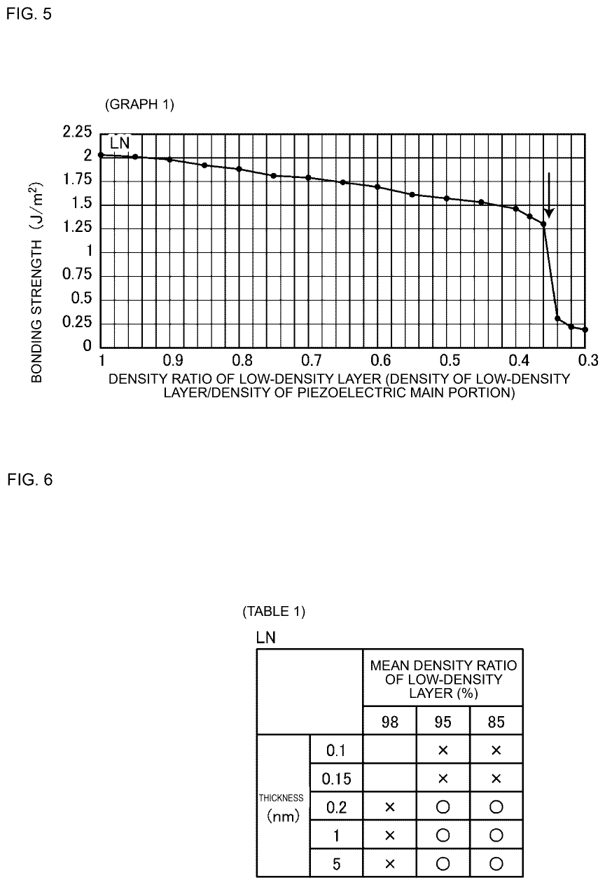

FIG. 5 is a graph describing a relationship between the density ratio of a low-density layer in a first example, and the bonding strength. The horizontal axis in graph 1 illustrated in FIG. 5 indicates the mean density ratio of the low-density layer 23 with respect to the densities of the first piezoelectric layer 21 and the second piezoelectric layer 22. The mean density of the low-density layer 23 indicates the mean value of the overall density including the first portion and the second portion having different densities in a plan view. The vertical axis in graph 1 indicates the bonding strength of the piezoelectric layer 20. The bonding strength is the strength exerted to separate the first piezoelectric layer 21 and the second piezoelectric layer 22 with breakage of the low-density layer 23 serving as a boundary portion, and is measured by a blade cracking method.

As illustrated in FIG. 5, the bonding strength of the piezoelectric layer 20 in the first example gradually decreases as the density ratio of the low-density layer 23 decreases. The bonding strength sharply drops when the mean density ratio of the low-density layer 23 with respect to the densities of the first piezoelectric layer 21 and the second piezoelectric layer 22 is changed from 36% to 34%. As generally known, a layer with a bonding strength less than or equal to 0.5 J/m² has insufficient resistance against reflow during implementation, and the error rate thus increases. In consideration of this point, in the first example, the mean density ratio of the low-density layer 23 is preferably greater than or equal to 36%, for example, with respect to the densities of the first piezoelectric layer 21 and the second piezoelectric layer 22.

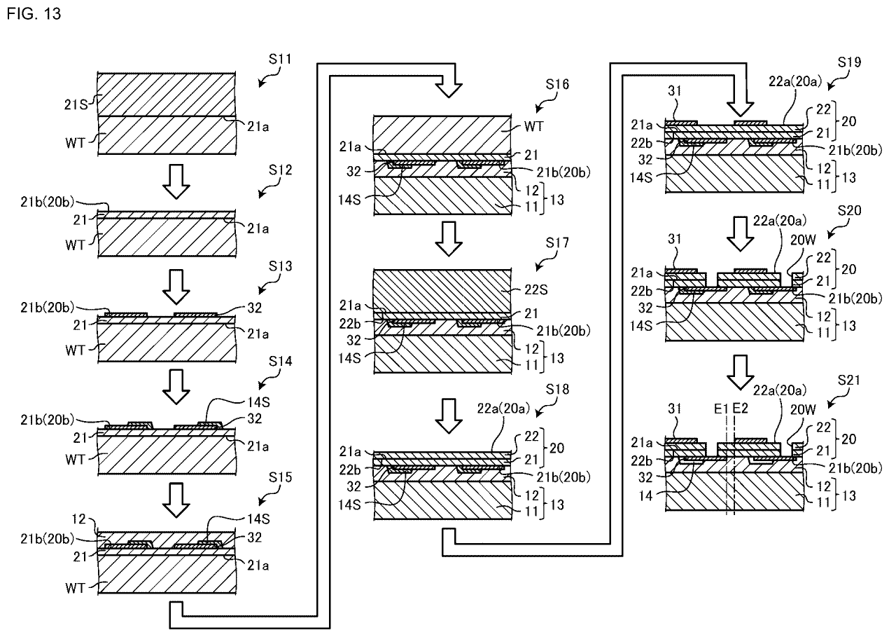

FIG. 6 is a table describing a relationship, in an acoustic wave resonator according to the first example, between a mean density ratio of the low-density layer, the thickness of the low-density layer, and the presence/absence of an unwanted wave attenuation effect. Table 1 in FIG. 6 illustrates evaluation results of resonance characteristics of evaluation samples fabricated to have the low-density layers 23 that vary in mean density and thickness from each other. In Table 1, circles indicate samples having an unwanted wave attenuation effect, and crosses indicate samples having no unwanted wave attenuation effect. The method for manufacturing the low-density layers 23 that differ in mean density and thickness from each other is described with reference to FIG. 13 to FIG. 15.

As illustrated in FIG. 6, when the low-density layer 23 has a thickness of 0.1 nm or 0.15 nm, the sample has no unwanted wave attenuation effect regardless of whether the mean density of the low-density layer 23 is lowered to 85% with respect to the densities of the first piezoelectric layer 21 and the second piezoelectric layer 22, for example. When the low-density layer 23 has a thickness within a range greater than or equal to 0.2 nm and less than or equal to 5 nm, the sample has an unwanted wave attenuation effect when the mean density of the low-density layer 23 is lowered to less than or equal to 95% with respect to the densities of the first piezoelectric layer 21 and the second piezoelectric layer 22, for example. When the mean density ratio of the low-density layer 23 is 98%, the sample has no unwanted wave attenuation effect in an area in which the low-density layer 23 has a thickness less than or equal to 5 nm, for example.

From the above results, in the first example, the low-density layer 23 preferably has a thickness greater than or equal to 0.2 nm, for example. The mean density of the low-density layer 23 is preferably less than or equal to 95% with respect to the densities of the first piezoelectric layer 21 and the second piezoelectric layer 22, for example.

When the low-density layer 23 has an excessively large thickness, resonance characteristics of a main wave may be attenuated. However, when the acoustic wave resonator 10 is fabricated to increase the thickness of the low-density layer 23 to approximately 30 nm, and the characteristics are measured, no attenuation of the resonance characteristics is observed. The measurements have thus revealed that the low-density layer 23 with a thickness within a range greater than or equal to 0.2 nm and less than or equal to 30 nm, for example, can achieve an unwanted wave attenuation effect and reduce attenuation of resonance characteristics of a main wave.

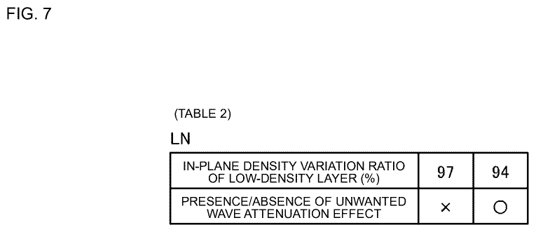

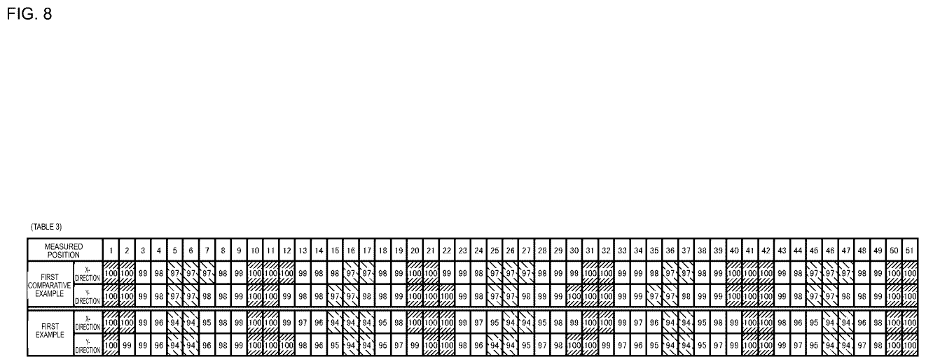

FIG. 7 is a table describing a relationship, in the acoustic wave resonator according to the first example, between an in-plane density variation ratio of the low-density layer and the presence/absence of an unwanted wave attenuation effect. FIG. 8 is a table describing in-plane density distribution of low-density layers according to the first example and a first comparative example.

Table 2 in FIG. 7 illustrates a relationship between an in-plane density variation ratio of the low-density layer 23 and the presence/absence of an unwanted wave attenuation effect when the mean density of the low-density layer 23 is 95% with respect to the densities of the first piezoelectric layer 21 and the second piezoelectric layer 22, and the thickness of the low-density layer 23 is 2 nm. The in-plane density variation ratio of the low-density layer 23 indicates a ratio between the lowest density of the in-plane density distribution of the low-density layer 23 and the highest density of the in-plane density distribution of the low-density layer 23 (“lowest density in the second portion of the low-density layer 23”/“highest density in the first portion of the low-density layer 23”).

As illustrated in FIG. 7, when the in-plane density variation ratio of the low-density layer 23 is 97%, for example, the acoustic wave resonator has no unwanted wave attenuation effect. In contrast, when the in-plane density variation ratio of the low-density layer 23 is 94%, for example, the acoustic wave resonator has an unwanted wave attenuation effect. This is because, in accordance with the in-plane density variation ratio of the low-density layer 23, unwanted waves adjacent in the in-plane direction vary in resonance state, and each interferes with the resonance state of the other. Thus, unwanted waves are reduced. As the in-plane density variation ratio of the low-density layer 23 is higher, each unwanted wave interferes with the resonance state of the adjacent wave, and thus the unwanted wave attenuation effect increases further. Thus, when the in-plane density variation ratio of the low-density layer 23 is less than or equal to 94%, for example, the acoustic wave resonator reliably has an unwanted wave attenuation effect.

Table 3 in FIG. 8 illustrates in-plane density distribution in cases when the in-plane density variation ratio of the low-density layer 23 in FIG. 7 is 94% (first example), and when the density variation ratio is 97% (first comparative example).

The in-plane density distribution of the low-density layer 23 illustrated in FIG. 8 is measured in the following manner. The piezoelectric layer 20 is shaved to cause the low-density layer 23 to appear on the outer surface, and then smoothed. Thereafter, the surface is cleaned by Ar ion beam irradiation and a chemical solution in a vacuum, and then an aluminum (Al) thin film with an extremely small uniform thickness is formed. The surface is measured by auger electron spectroscopy (AES) at a predetermined pitch in the X-direction and the Y-direction. In the example in FIG. 8, a range of 5 μm is measured at a pitch of 0.1 μm in each of the X-direction and the Y-direction, for example. Relative density distribution in the in-plane direction is calculated based on the ratio between aluminum (Al) and niobium (Nb). FIG. 8 illustrates values normalized with respect to the highest density defined as 100%.

As illustrated in FIG. 8, in the low-density layer 23 in the first example, an area with a relatively high density (hereafter referred to as a first portion) in the in-plane direction and an area with a relatively low density (hereafter referred to as a second portion) in the in-plane direction are alternately disposed in a predetermined cycle. The first portion and the second portion are cyclically alternately disposed in the X-direction and the Y-direction. The relative density of the first portion is 100%, and the relative density of the second portion is 94%. More specifically, in the low-density layer 23 according to the first example, the ratio between the highest density of the first portion and the lowest density of the second portion is less than or equal to 94%, for example. Between each first portion and the corresponding second portion, an area with a relative density in the range from 95% to 99% is disposed, for example.

Similarly, in the low-density layer 23 according to the first comparative example, the first portion and the second portion are alternately disposed in a predetermined cycle in the in-plane direction. The relative density of the first portion is 100%, and the relative density of the second portion is 97%, for example. Between each first portion and the corresponding second portion, an area having a relative density in the range from 98% to 99% is disposed, for example.

As described above, in the first example, the mean density ratio of the low-density layer 23 is preferably greater than or equal to 36% and less than or equal to 95% with respect to the densities of the first piezoelectric layer 21 and the second piezoelectric layer 22. Preferably, the thickness of the low-density layer 23 is greater than or equal to 0.2 nm and less than or equal to 30 nm, for example. Preferably, the in-plane density variation ratio of the low-density layer 23 (ratio between the highest density of the first portion and the lowest density of the second portion) is less than or equal to 94%, for example. Thus, the acoustic wave resonator 10 according to the first example can achieve an unwanted wave attenuation effect while reducing deterioration of resonance characteristics of a main wave.

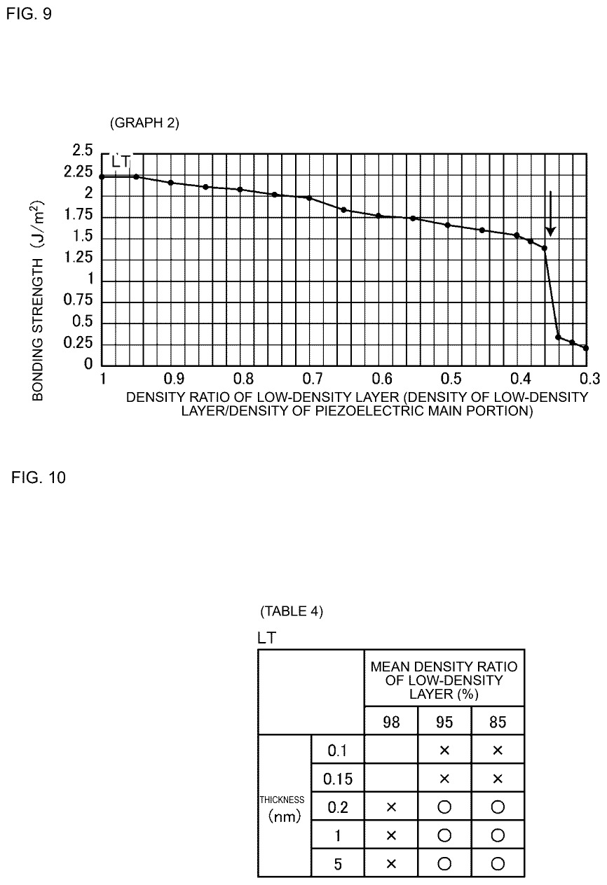

With reference to FIG. 9 to FIG. 12, a low-density layer 23 in t acoustic wave resonator 10 according to the second example is described in detail. An acoustic wave resonator 10 according to a second example differs from the acoustic wave resonator 10 according to the first example in that the first piezoelectric layer 21, the second piezoelectric layer 22, and the low-density layer 23 in the piezoelectric layer 20 include the same monocrystals of lithium tantalate (LiTaO₃).

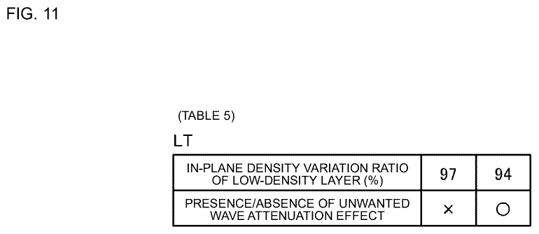

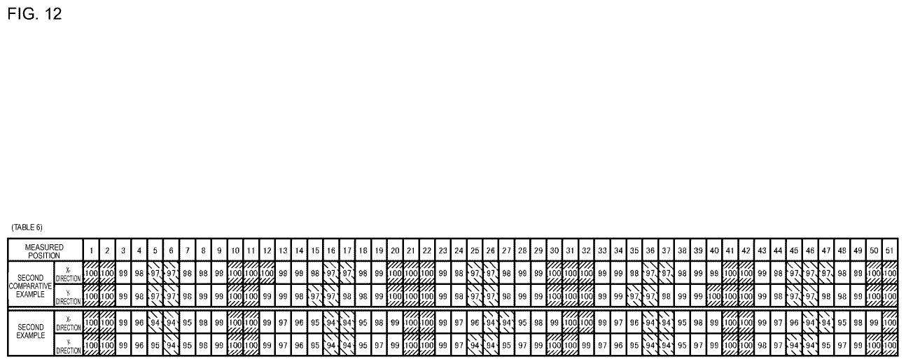

FIG. 9 is a graph describing a relationship between the density ratio of a low-density layer according to a second example and the bonding strength. FIG. 10 is a table describing the relationship, in an acoustic wave resonator according to the second example, between the mean density ratio of the low-density layer, the thickness of the low-density layer, and the presence/absence of an unwanted wave attenuation effect. FIG. 11 is a table describing the relationship, in the acoustic wave resonator according to the second example, between the in-plane density variation ratio of the low-density layer and the presence/absence of an unwanted wave attenuation effect. FIG. 12 is a table describing in-plane density distribution of low-density layers according to the second example and a second comparative example.

As illustrated in FIG. 9 to FIG. 12, the acoustic wave resonator 10 according to the second example has the same results as the acoustic wave resonator 10 according to the first example illustrated in FIG. 5 to FIG. 8. More specifically, in a structure in which the piezoelectric layer 20 includes monocrystals of lithium tantalate (LiTaO₃), the mean density ratio of the low-density layer 23 is preferably greater than or equal to 36% and less than or equal to 95% with respect to the densities of the first piezoelectric layer 21 and the second piezoelectric layer 22, for example. In addition, the thickness of the low-density layer 23 is preferably greater than or equal to 0.2 nm and less than or equal to 30 nm, for example. Preferably, the in-plane density variation ratio of the low-density layer 23 (ratio between the highest density of the first portion and the lowest density of the second portion) is less than or equal to 94%, for example. Thus, the acoustic wave resonator 10 according to the second example can achieve an unwanted wave attenuation effect while reducing deterioration of resonance characteristics of a main wave.

In the above example embodiments and examples, the details such as the number of piezoelectric layers, the number of laminated layers in the low-density layer, or the thickness are mere examples, and may be changed as appropriate. For example, three or more piezoelectric layers may be laminated, and a low-density layer may be between each pair of adjacent piezoelectric layers.

FIG. 13 is a diagram describing a non-limiting example of a method for manufacturing the acoustic wave resonator according to the first example embodiment. As illustrated in FIG. 13, a method for manufacturing the acoustic wave resonator 10 according to the present example embodiment includes a first wafer bonding process (step S11), a first wafer thinning process (step S12), a lower electrode forming process (step S13), a sacrificial layer forming process (step S14), an intermediate layer forming process (step S15), a bonding process (step S16), a second wafer bonding process (step S17), a second wafer thinning process (step S18), an upper electrode forming process (step S19), a piezoelectric-layer window-opening process (step S20), and a space forming process (step S21).

In the first wafer bonding process (step S11), a first wafer 2 including a first piezoelectric layer 21 that has not been processed is bonded to the main surface of a transfer substrate WT.

In the first wafer thinning process (step S12), the first wafer 21S is ground to be thinned. Thus, the first piezoelectric layer 21 is formed. A second main surface 21b of the first piezoelectric layer 21 is smoothed by grinding. In this smoothing, the piezoelectric layer surface is formed into a smooth surface including a continuous smooth area in which a surface roughness Rmax within 1 μm×1 μm falls within a range greater than or equal to 0.1 nm and less than or equal to 5 nm and the size of protrusions and recesses adjacent within a width of 0.2 μm falls within a range greater than or equal to 0.1 nm and less than or equal to 5 nm, for example.

In the lower electrode forming process (step S13), the pattern of the lower electrode 32 is formed on the second main surface 21b of the first piezoelectric layer 21 by a method such as lift-off. At this time, a metal film such as a routing wiring not illustrated is also formed on the second main surface 21b of the first piezoelectric layer 21.

In the sacrificial layer forming process (step S14), a sacrificial layer 14S is formed on the second main surface 21b of the first piezoelectric layer 21 to cover a portion of the lower electrode 32. The sacrificial layer 14S includes, for example, zinc oxide.

In the intermediate layer forming process (step S15), an insulator is deposited on the second main surface 21b of the first piezoelectric layer 21 to cover the lower electrode 32 and the sacrificial layer 14S, and the surface opposite to the first piezoelectric layer 21 is flattened and smoothed to form the intermediate layer 12 including the insulator.

In the bonding process (step S16), for example, the first piezoelectric layer 21 and the lower electrode 32 are bonded to the support 13 with the intermediate layer 12 interposed therebetween. Thereafter, the transfer substrate WT is removed from the first piezoelectric layer 21.

In the second wafer bonding process (step S17), a second wafer 22S including the second piezoelectric layer 22 that has not been processed is bonded to a first main surface 21a of the first piezoelectric layer 21. The second wafer 22S is a piezoelectric member having a different polarization direction from the first piezoelectric layer 21. The surface of the second wafer 22S before being bonded undergoes processing similar to smoothing of the first piezoelectric layer 21. More specifically, the surface of the second piezoelectric layer 22 is formed into a smooth surface including a continuous smooth area in which a surface roughness Rmax within 1 μm×1 μm falls within a range greater than or equal to 0.1 nm and less than or equal to 5 nm and the size of protrusions and recesses adjacent within a width of 0.2 μm falls within a range greater than or equal to 0.1 nm and less than or equal to 5 nm, for example.

The second wafer 22S is bonded by hydrophilic bonding or surface-activated bonding. Thus, the first piezoelectric layer 21 and the second piezoelectric layer 22 are directly bonded. When the first piezoelectric layer 21 and the second piezoelectric layer 22 having the above bonded surfaces are bonded by hydrophilic bonding or surface-activated bonding, and then further heated, the low-density layer 23 including the same material as and having the same crystal structure as the first piezoelectric layer 21 and the second piezoelectric layer 22 is formed at the bonding interface (in the area around an interface different in the polarization direction) between the first piezoelectric layer 21 and the second piezoelectric layer 22.

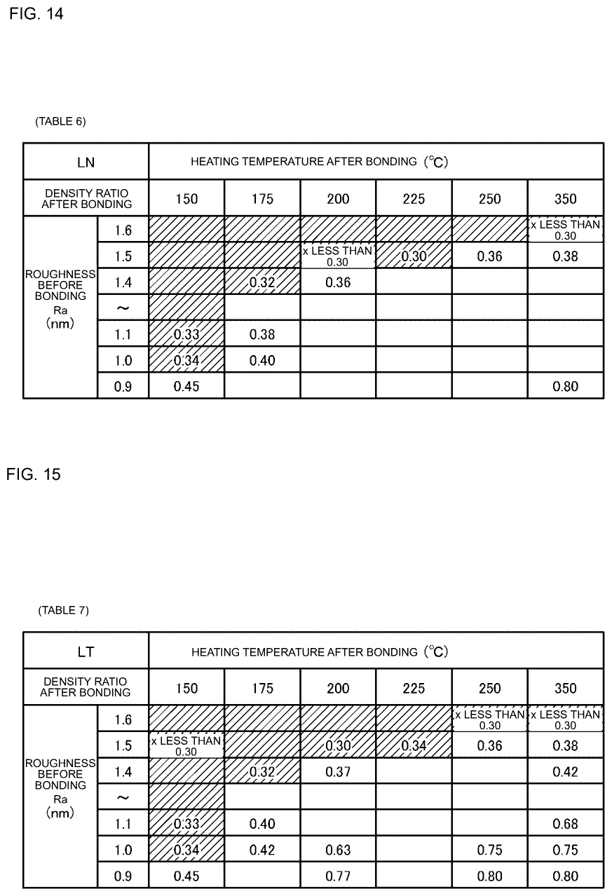

FIG. 14 is a table describing the relationship, in the piezoelectric layer in the first example, between the surface roughness before bonding, the heating temperature after bonding, and the mean density of the low-density layer. FIG. 15 is a table describing the relationship, in the piezoelectric layer in the second example, between the surface roughness before bonding, the heating temperature after bonding, and the mean density of the low-density layer.

In Table 6 in FIG. 14 and Table 7 in FIG. 15, areas of the low-density layer 23 with a mean density less than or equal to 0.34, more specifically, areas of the first piezoelectric layer 21 and the second piezoelectric layer 22 with excessively low bonding strength below a boundary value are hatched. Areas of the low-density layer 23 with a mean density greater than or equal to 0.36, more specifically, areas with sufficient bonding strength over the boundary value are not hatched.

The surface roughness Ra before hydrophilic bonding illustrated in FIG. 14 and FIG. 15 was measured by an atomic force microscope (AFM). More specifically, the surface roughness Ra was measured by the conditions below, using a device L-Trace II manufactured by Hitachi High-Tech Corporation.
The main setting parameters are as follows.
Cantilever Member: Si
Scanning Area: 10×10 μm
Scanning Frequency: 0.6 Hz
Number of X and Y Data Pieces: 1024×1024

As illustrated in FIG. 14 and FIG. 15, in either the first example or the second example, when the surface roughness Ra before hydrophilic bonding is reduced, the low-density layer 23 has higher density. When the heating temperature after hydrophilic bonding is raised, the low-density layer 23 has a higher density.

More specifically, when the surface roughness Ra of the piezoelectric layer (the first piezoelectric layer 21 and the second piezoelectric layer 22) before hydrophilic bonding is greater than or equal to 0.9 nm and less than or equal to 1.1 nm, and the heating temperature after bonding is within the range greater than or equal to 150 °C and less than or equal to 175 °C, the low-density layer 23 has a density ratio around the boundary value, for example. When the surface roughness Ra of the piezoelectric layer before hydrophilic bonding is greater than or equal to 1.4 nm and less than or equal to 1.5 nm, and the heating temperature after bonding is within the range greater than or equal to 175 °C and less than or equal to 250 °C, the low-density layer 23 has a density ratio around the boundary value, for example.

More specifically, in step S12 described above, a surface of the first piezoelectric layer 21 having the surface roughness Ra greater than or equal to 0.075 nm and less than or equal to 1.5 nm and having an alternately expanded mean interval (≈a half cycle) between a protrusion and a recess (peak and valley) adjacent to each other within a range greater than or equal to 10 nm and less than or equal to 100 nm is formed, for example.

In the second wafer bonding process (step S17), the surface of the second piezoelectric layer 22 is formed to have a surface roughness Ra within the range of 1 μm×1 μm greater than or equal to 0.075 nm and less than or equal to 1.5 nm, and to have an alternately expanded mean interval (≈a half cycle) between a protrusion and a recess (peak and valley) adjacent to each other within a range greater than or equal to 10 nm and less than or equal to 100 nm, for example. The first piezoelectric layer 21 and the second piezoelectric layer 22 are directly bonded by, for example, hydrophilic bonding or surface-activated bonding. The heating temperature after bonding is maintained at greater than or equal to 125 °C and less than or equal to 350 °C, for example. Thus, the low-density layer 23 including the same material as and having the same crystal structure as the first piezoelectric layer 21 and the second piezoelectric layer 22, and having low density and a density variation in the in-plane direction is formed at the bonding interface.

When manufactured to have the above surface roughness and at the heating temperature after bonding, the low-density layer 23 has a thickness approximately greater than or equal to 0.2 nm and less than or equal to 30 nm, has a mean density approximately greater than or equal to 30% and less than or equal to 98% of that of the first piezoelectric layer 21 and the second piezoelectric layer 22, and has an in-plane density variation ratio (lowest density in the second portion/highest density in the first portion) approximately greater than or equal to 80% and less than or equal to 98%, for example.

As the surface roughness Ra of the first piezoelectric layer 2 and the second piezoelectric layer 22 before bonding is increased, and the heating temperature after hydrophilic bonding is lowered, the low-density layer 23 can further increase the thickness. As the protrusions and recesses on the surfaces of the first piezoelectric layer 21 and the second piezoelectric layer 22 before bonding are greater, and the heating temperature after hydrophilic bonding is lowered further, the mean density of the low-density layer 23 can be lowered relative to the densities of the first piezoelectric layer 21 and the second piezoelectric layer 22. To increase the difference in in-plane density variation of the low-density layer 23, the peak-valley interval on the surface before bonding may be increased while increasing the surface roughness of the first piezoelectric layer 21 and the second piezoelectric layer 22 before bonding, and the heating temperature after hydrophilic bonding may be further raised.

As described above, as illustrated in FIG. 14 and FIG. 15, in step S12 and step S17, when the surface roughness Ra of the first piezoelectric layer 21 and the second piezoelectric layer 22 before hydrophilic bonding and the heating temperature after bonding are adjusted as appropriate, the low-density layer 23 having intended density, thickness, and in-plane density variation ratio is formed.

The surface roughness Ra and the heating temperature illustrated in FIG. 14 and FIG. 15 are mere examples, and may be changed as appropriate. The surface roughness Ra and the heating temperature may be out of the ranges of the surface roughness Ra and the heating temperature illustrated in FIG. 14 and FIG. 15.

With reference back to FIG. 13, in the second wafer thinning process (step S18), the second wafer 22S is thinned by grinding. Thus, the second piezoelectric layer 22 is formed. A third main surface 22a of the second piezoelectric layer 22 is smoothed by grinding. In the present example embodiment, the second piezoelectric layer 22 is ground to have the same thickness as the first piezoelectric layer 21.

In the upper electrode forming process (step S19), the upper electrode 31 is formed on the third main surface 22a of the second piezoelectric layer 22. In the present example embodiment, the upper electrode 31 is formed by, for example, lift-off. At this time, a metal film such as a routing wiring may also be formed on the third main surface 22a of the second piezoelectric layer 22. Alternatively, after the upper electrode 31 is formed, a layer including an insulator such as a protection film may be formed.

In the piezoelectric layer window-opening forming process (step S20), a window is formed in the piezoelectric layer 20. In the present example embodiment, a resist pattern is formed, and dry etching is then performed to thus form an open window 20W and a through-hole not illustrated.

In the space forming process (step S21), an etching gas or an etchant is introduced into a through-hole not illustrated to remove the sacrificial layer 14S and to form the recess 14.

After these processes, the support 13 is diced. In the example illustrated in FIG. 13, a portion, in the area between a dot-and-dash line E1 and a dot-and-dash line E2, not including a functional electrode (the upper electrode 31 and the lower electrode 32) is removed for dicing. Thus, the acoustic wave resonator 10 according to the present example embodiment can be manufactured. The processes described above are illustrated merely schematically, and may be changed as appropriate.

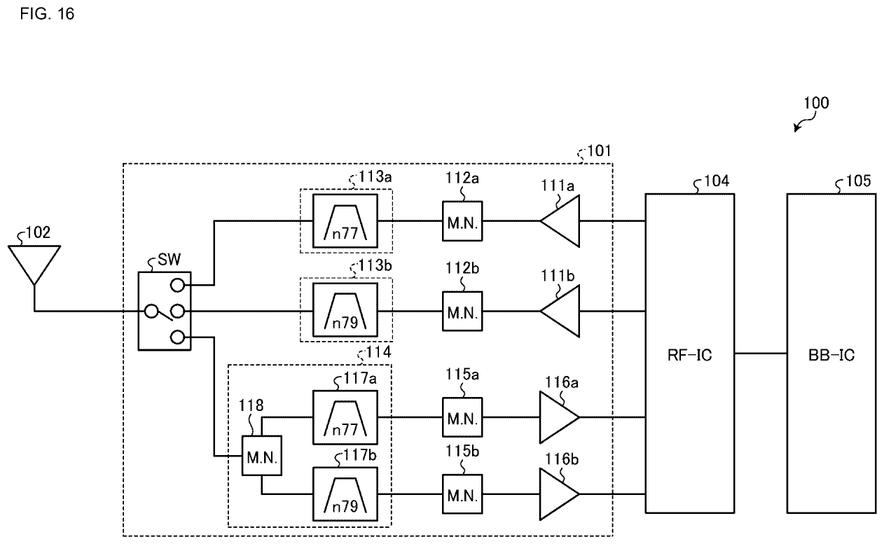

FIG. 16 is a diagram of a communication device according to a second example embodiment. A communication device 100 according to a second example embodiment is, for example, a mobile phone, a mobile terminal such as a smartphone or a tablet terminal, or a personal computer having a communication function. Alternatively, the communication device 100 may perform communications between base stations and a backhaul communication between a base station and a core network.

As illustrated in FIG. 16, the communication device 100 includes a front end module 101, an antenna 102, a radio frequency integrated circuit (RF-IC) 104, and a baseband integrated circuit (BB-IC) 105.

The BB-IC 105 provides a baseband signal processing circuit. The BB-IC 105 provides a baseband signal to an RF-IC 104. The RF-IC 104 performs high-frequency signal processing on transmission and reception signals.

The front end module 101 is connected between the antenna 102 and the RF-IC 104. In the communication device 100, a high-frequency transmission signal is output from the front end module 101 to the antenna 102, and a high-frequency reception signal from the antenna 102 can be received by the front end module 101.

More specifically, the front end module 101 includes a switch SW, power amplifiers 111a and 111b, matching circuits 112a and 112b, transmitting filters 113a and 113b, a multiplexer 114, matching circuits 115a and 115b, and low-noise amplifiers 116a and 116b.

To transmit a high-frequency signal, the switch SW is switched to the transmitting filter 113a or the transmitting filter 113b. The high-frequency transmission signal output from the RF-IC 104 is amplified by the power amplifier 111a or the power amplifier 111b, and input into the transmitting filter 113a or the transmitting filter 113b through the matching circuit 112a or 112b.

The band of the transmitting filter 113a is, for example, n77 the 5G new radio (NR) standard. The frequency range of n 77 in the 5GNR is higher than or equal to 3.3 GHz and lower than or equal to 4.2 GHz, for example. The band of the transmitting filter 113b is, for example, n79 of the 5GNR standard. The frequency range of n 79 in the 5GNR is higher than or equal to 4.4 GHz and lower than or equal to 5.0 GHz, for example.

The high-frequency transmission signal that has passed through the transmitting filter 113a or the transmitting filter 113b is fed to the antenna 102.

To receive a high-frequency signal, the switch SW is switched to the multiplexer 114. The multiplexer 114 includes receiving filters 117a and 117b, and a matching circuit 118. The band of the receiving filter 117 a is, for example, n77 of the 5GNR standard. The band of the receiving filter 117 b is, for example, n79 of the 5GNR standard.

A reception signal from the antenna 102 passes through the receiving filter 117a or the receiving filter 117b after passing through the matching circuit 118. The high-frequency reception signal that has passed through the receiving filter 117a or the receiving filter 117b is transmitted to the RF-IC 104 through the matching circuit 115a or 115b and the low-noise amplifier 116a or 116b.

In the communication device 100 according to the present example embodiment, at least one of the transmitting filters 113a and 113b or the receiving filters 117a and 117b in the multiplexer 114 is an acoustic wave filter including the acoustic wave resonator 10 described above. The front end module 101 includes at least one of the transmitting filters 113a and 113b or the receiving filters 117a and 117b in the multiplexer 114. The communication device 100 includes the front end module 101.

The structure of the communication device 100 illustrated in FIG. 16 is merely schematically illustrated, and may be changed as appropriate. The bands of the transmitting filters 113a and 113b and the receiving filters 117a and 117b are mere examples, and other communication standards are also applicable.

The example embodiments described above are provided to facilitate understanding of the present invention, not to limit the present invention. The present invention may be modified or improved without departing from the gist of the invention, and includes the equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave resonator, comprising:
a support that includes a support board;
a piezoelectric layer at a main surface of the support; and
a plurality of functional electrodes on opposite main surfaces of the piezoelectric layer; wherein
the piezoelectric layer includes:
a first piezoelectric layer having a polarization direction oriented in a first direction;
a second piezoelectric layer between the first piezoelectric layer and the main surface of the support, and having a polarization direction oriented in a second direction different from the first direction; and
a low-density layer between the first piezoelectric layer and the second piezoelectric layer, and having a density lower than a density of the first piezoelectric layer and a density of the second piezoelectric layer; wherein
the first piezoelectric layer, the second piezoelectric layer, and the low-density layer include monocrystals; and
the low-density layer includes a first portion and a second portion having different densities in a plan view.

2. The acoustic wave resonator according to claim 1, wherein the low-density layer includes a same material as at least one of the first piezoelectric layer or the second piezoelectric layer, and includes a monocrystal having a same crystal structure and a same crystal orientation as the at least one of the first piezoelectric layer or the second piezoelectric layer.

3. The acoustic wave resonator according to claim 1, wherein the density of the low-density layer is greater than or equal to 36% of the density of the first piezoelectric layer and the density of the second piezoelectric layer.

4. The acoustic wave resonator according to claim 1, wherein the density of the low-density layer is less than or equal to 95% of the density of the first piezoelectric layer and the density of the second piezoelectric layer.

5. The acoustic wave resonator according to claim 1, wherein a thickness of the low-density layer is greater than or equal to 0.2 nm and less than or equal to 30 nm.

6. The acoustic wave resonator according to claim 1, wherein
in the low-density layer, the first portion is an area with a relatively high density, and the second portion is an area with a relatively low density; and
a ratio between a highest density in the first portion and a lowest density in the second portion is less than or equal to 94%.

7. The acoustic wave resonator according to claim 1, wherein the polarization direction intersects a thickness direction of the piezoelectric layer.

8. The acoustic wave resonator according to claim 1, wherein the acoustic wave resonator is a bulk acoustic wave resonator.

9. The acoustic wave resonator according to claim 1, wherein the support board includes silicon.

10. The acoustic wave resonator according to claim 1, wherein the support includes an intermediate insulating layer between the support board and the piezoelectric layer.

11. The acoustic wave resonator according to claim 1, wherein the support includes a recess on a surface facing a main surface of the piezoelectric layer.

12. The acoustic wave resonator according to claim 1, wherein the support includes the monocrystals include monocrystals of lithium niobate or lithium tantalate.

13. The acoustic wave resonator according to claim 1, wherein the support includes an acoustic multilayer film.

14. An acoustic wave filter, comprising:
the acoustic wave resonator according to claim 1.

15. A front end module, comprising:
the acoustic wave filter according to claim 14.

16. A communication device, comprising:
the front end module according to claim 15.

17. The communication device according to claim 16, further comprising an antenna, a radio frequency integrated circuit, and a baseband integrated circuit.

18. The communication device according to claim 16, wherein the communication device is a mobile phone, a mobile terminal, or a computer.

19. The communication device according to claim 16, wherein the acoustic wave resonator is included in at least one of a transmitting filter or at least one of a receiving filter.

20. The communication device according to claim 19, wherein the acoustic wave resonator is included in a multiplexer.
